(19) United States
(12) Patent Application Publication
(10) Pub. No.: US 2003/0224546 A1
(43) Pub. Date: Dec. 4, 2003

(54) Method and apparatus for reducing noise in electrical power supplied to a semiconductor

(76) Inventors: Wenjun W. Chen, Fremont, CA (US); Hong-Him Lim, San Jose, CA (US)

Correspondence Address: B. Noel Kivlin, Meyertons, Hood, Kilvin, Kowart & Goetzel, P.C., P.O. Box 398, Austin, TX, 78767-0398, US

(21) Appl. No.: 10/159,402

(22) Filed: May 30, 2002

(51) Int. Cl. H01L 21/00; H01L 21/20

(52) U.S. Cl. 438/19; 438/393

(57) ABSTRACT

A method and apparatus for decoupling a voltage supply from a semiconductor device is provided. A substrate has a plurality of spaced apart electrical connections positioned on thereon, wherein at least first and second ones of the connections are coupled to first and second terminals of a voltage supply respectively. A capacitor is coupled to the substrate and interstitially positioned within the spaced apart connections. The capacitor has first and second leads coupled with the first and second terminals of the voltage supply. A semiconductor device is coupled to the substrate in mating relationship with the pattern of spaced apart electrical connections, wherein the capacitor is positioned below the semiconductor device and immediately adjacent the voltage supply terminals of the semiconductor device.

### BACKGROUND OF THE INVENTION

1. Field of the Invention

This invention relates generally to reducing noise in an electrical power supply, and, more particularly, to a method and apparatus for providing localized filtering of electrical power.

2. Description of the Related Art

Providing electrical power to electronic devices is becoming increasingly complex. Over time, voltage levels used to power various electronic devices have fallen dramatically. Many electronic components now operate at levels below 2 volts. As the operating voltage level has fallen, sensitivity to variations in the voltage level has become more significant. That is, variations that were once insignificant, as compared to the overall voltage level, now constitute a significant percentage variation in the supplied voltage.

These variations, or noise, may lead to faulty operation of the electronic component. That is, an electronic component operating at 5 Volts nominally may be capable of tolerating a 0.2 Volt variation without adversely affecting the operation of the electronic component. However, when the voltage level of the electronic component is at 2 Volts, the same 0.2 Volt variation is a 10 percent deviation, which may cause unpredictable and/or improper operation of the electronic component.

Historically, these variations have been removed, or at least reduced, by adding decoupling capacitors to filter or otherwise smooth the voltage provided to the electronic components. Typically, as shown in FIG. 1, decoupling capacitors 100 have been located adjacent an electronic component 102 to which electrical power is being supplied. Commonly, the capacitors 100 have been disposed on a printed circuit board 104 extending about the periphery of the component 102, such as an integrated circuit device. All other things being equal, the closer the capacitors 100 are to the integrated circuit device 102, the more substantial the effect they have on the electrical power delivered thereto. However, the number of capacitors 100 needed to prevent these relatively small variations in the supply voltage has become sufficiently large that it is problematic to locate enough capacitors sufficiently close to the device 102 in the region surrounding the device 102.

### SUMMARY OF THE INVENTION

In one aspect of the present invention, a method is provided for decoupling a voltage supply from a semiconductor device. The method comprises forming a pattern of spaced apart electrical connections on a first surface of a substrate wherein at least first and second ones of the connections are coupled to first and second terminals of the voltage supply respectively. A capacitor is located on a second surface of the substrate within the spaced apart connections, the capacitor having first and second leads coupled with the first and second ones of the connections. A semiconductor device is coupled to the substrate in mating relationship with the pattern of spaced apart electrical connections, wherein the capacitor is positioned adjacent the semiconductor device.

In another aspect of the present invention, an apparatus is provided. The apparatus is comprised of a substrate, a plurality of spaced apart electrical connections, a capacitor, and a semiconductor device. The plurality of spaced apart electrical connections are positioned on a first surface of the substrate wherein at least first and second ones of the connections are coupled to first and second terminals of a voltage supply respectively. The capacitor is coupled to a second surface of the substrate and positioned within the spaced apart connections. The capacitor has first and second leads coupled with the first and second ones of the connections. The semiconductor device is coupled to the substrate in mating relationship with the pattern of spaced apart electrical connections, wherein the capacitor is positioned adjacent the semiconductor device.

### BRIEF DESCRIPTION OF THE DRAWINGS

The invention may be understood by reference to the following description taken in conjunction with the accompanying drawings, in which the leftmost significant digit(s) in the reference numerals denote(s) the first figure in which the respective reference numerals appear, and in which:

FIG. 1 illustrates a perspective view of an electronic system that includes a plurality of capacitors arranged to reduce noise in a voltage supplied to a semiconductor device;

FIG. 2 schematically illustrates a cross sectional side view of a semiconductor device mounted on a printed circuit board;

FIG. 3 schematically illustrates an enlarged cross sectional side view of an embodiment of the semiconductor device and printed circuit board of FIG. 2;

FIG. 4 illustrates a top view of one embodiment the printed circuit board of FIGS. 2 and 3 in a region generally lying beneath the semiconductor device;

FIG. 5 illustrates a top view of an alternative embodiment the printed circuit board of FIGS. 2 and 3 in a region generally lying beneath the semiconductor device; and

FIG. 6 illustrates a cross sectional side view of the printed circuit board of FIGS. 2-5 in a region lying beneath the semiconductor device.

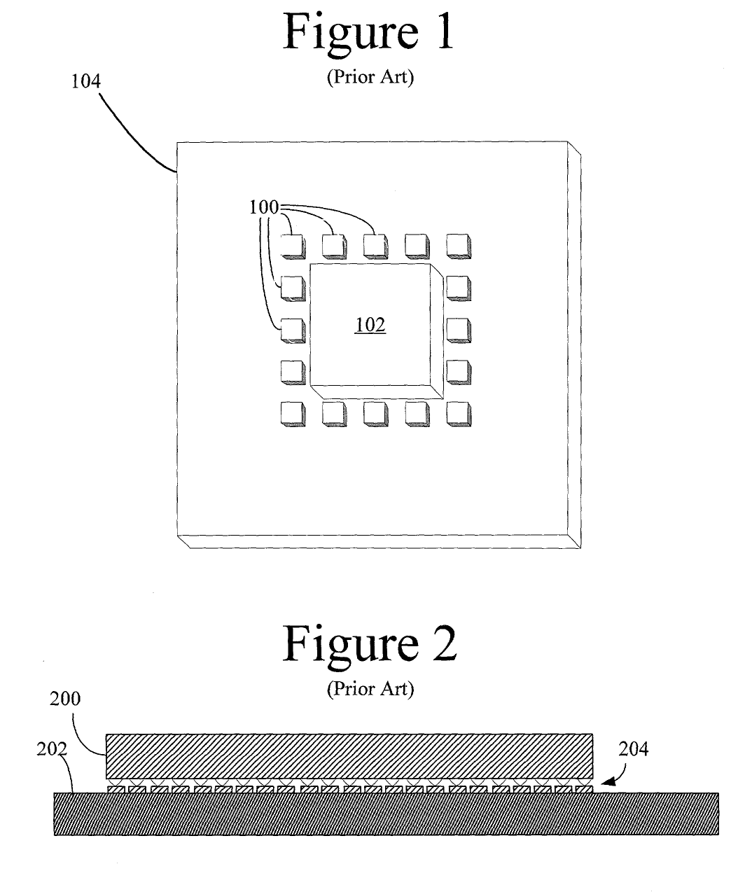

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but, on the contrary, the intention is to cover all modifications, equivalents, and alternatives falling within the scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

Illustrative embodiments of a method and apparatus for improving the supply of power to a semiconductor device are shown in FIGS. 2-6. As will be readily apparent to those skilled in the art upon a complete reading of the present application, the present method and apparatus are applicable to a variety of electronic or electrical systems, including, but not limited to, logic devices, memory devices, processors, and the like.

Turning now to FIG. 2, a stylistic cross sectional side view of a conventional semiconductor device 200 mounted on a substrate, such as a printed circuit board 202 is shown. In the illustrated embodiment, an electrical connection 204 between the printed circuit board 202 and the semiconductor device 200 is a typical ball grid array. Those skilled in the art, however, will appreciate that other types of electrical connections may be employed without departing from the scope of the instant invention. For example, the electrical connection 204 may take the form of pins and sockets soldered or otherwise mechanically coupled together, or may include an intermediary device, such as a zero insertion force socket, or the like.

A physical mounting mechanism is not illustrated herein, as such devices are well known to those skilled in the art, and its inclusion in the drawing might serve to obfuscate the instant invention. Generally, it is sufficient to understand that the semiconductor device 204 is fixed to the printed circuit board 202 such that the electrical connection 204 is well established.

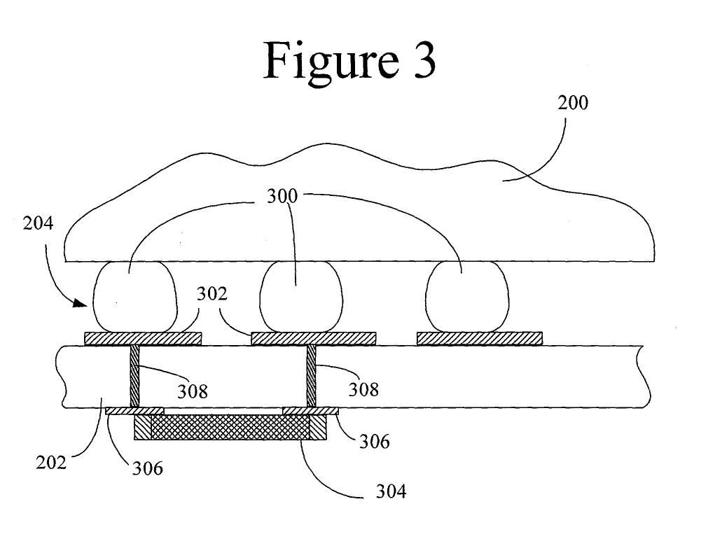

Generally, as shown in FIG. 3, the electrical connection 204 is comprised of a plurality of spaced-apart individual connectors 300 on the semiconductor device 200, which are arranged in a pattern to mate with a corresponding plurality of spaced-apart individual connectors or pads 302 located on the printed circuit board 202. The individual connectors 300, 302 provide electrical pathways between the semiconductor device 200 and the printed circuit board 202 such that information may be exchanged therebetween, and electrical power may be provided thereto. That is, at least one, and in some cases multiple ones, of the connectors 300 on the semiconductor device 200 are designed to receive a supply voltage (e.g., 2V, 5V, ground, etc.). That is, electrical power is supplied to the printed circuit board 202, which, in turn, routes the electrical power through traces, wires, lines, etc. to the appropriate connector 302 on the printed circuit board 202. The connector 302 passes the supply voltage to circuitry within the semiconductor device through the mating connector 300.

One or more decoupling capacitors 304 are located on an opposite side of the printed circuit board 202 substantially below the semiconductor device 200, as opposed to being positioned about the periphery of the semiconductor device 200. In one embodiment, the decoupling capacitors 304 may extend interstitially relative to the array of connectors 302. This interstitial spacing allows the decoupling capacitors 304 to be located in close proximity to the connectors 302 to which they are to be electrically coupled. In particular, the capacitors 304 may be located immediately adjacent the one or more connectors 302 that are coupled to receive the supply voltage. In the embodiment illustrated in FIG. 3, the capacitor 304 is shown positioned on a bottom surface of the printed circuit board 202, opposite the semiconductor device 200. The capacitor 304 is electrically coupled to connectors or pads 306 located on the bottom surface of the printed circuit board 202. A via 308 extends through the printed circuit board 202, establishing an electrical connection between the connectors 302, 306 located on opposite sides of the printed circuit board 202. This embodiment allows the decoupling capacitors 304 to be located adjacent the connectors 302.

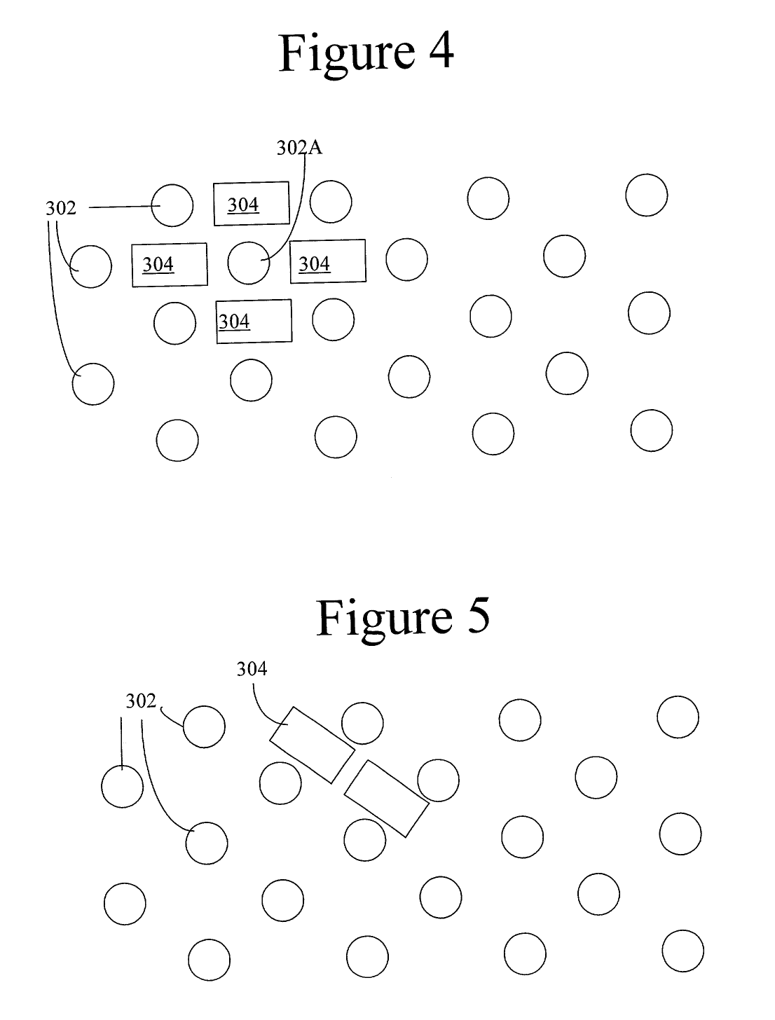

Turning now to FIGS. 4 and 5, exemplary patterns of the connectors 302 and the decoupling capacitors 304 are illustrated. Generally, the capacitors 304 are positioned between the connectors 302 and adjacent those connectors 302 that are coupled to receive the supply voltage. For example, in the embodiment illustrated in FIG. 4, the capacitors 304 are positioned immediately about the connector 302a, which is coupled in a conventional manner to a power plane (not shown) within the printed circuit board 202 to receive the supply voltage. Those skilled in the art will appreciate that more than one of the connectors 302 may be coupled to receive a supply voltage, and thus, one or more arrangements of decoupling capacitors 304 may be located adjacent each of these connectors 302 to ensure that noise, voltage droop, and other undesirable effects are reduced.

In the embodiment illustrated in FIGS. 4 and 5, the connectors 302 are configured in a conventional pattern that involves adjacent rows of the connectors 302 being misaligned or out of phase so as to provide a relatively dense but evenly distributed population of the connectors 302. This configuration allows for multiple arrangements of the capacitors 304 within the spaces between the connectors 302. For example, as shown in FIG. 4, each of the capacitors 304 may be located substantially within a single row of the connectors 302 in the space between adjacent ones of the connectors 302. Likewise, although not illustrated, each of the capacitors 304 could be located substantially within a single column of the connectors 302 in the space between adjacent ones of the connectors 302.

Alternatively, as illustrated in FIG. 5, the configuration of the connectors 302 yields diagonal paths that are substantially free of the connectors 302. Thus, the capacitors 304 may be positioned diagonally in an end-to-end arrangement adjacent the connectors 300 that are coupled to receive the supply voltage. It should be appreciated that the configuration of the connectors 302 yields a second set of diagonal paths substantially perpendicular to the diagonal paths on which the capacitors 304 are located in FIG. 5. This second set of diagonal paths may be used instead of or in conjunction with the first set of diagonal paths.

Those skilled in the art will appreciate that the arrangements of the capacitors 304 illustrated in FIGS. 4 and 5 are not mutually exclusive. That is, the patterns shown in FIGS. 4 and 5 may be used conjointly to position a sufficient number and type of capacitors 304 adjacent each of the connectors 302 that are coupled to the power supply. More specifically, where useful, all of the patterns of the capacitors 304 discussed in conjunction with FIGS. 4 and 5 may be intermixed in a single application to provide adequate decoupling.

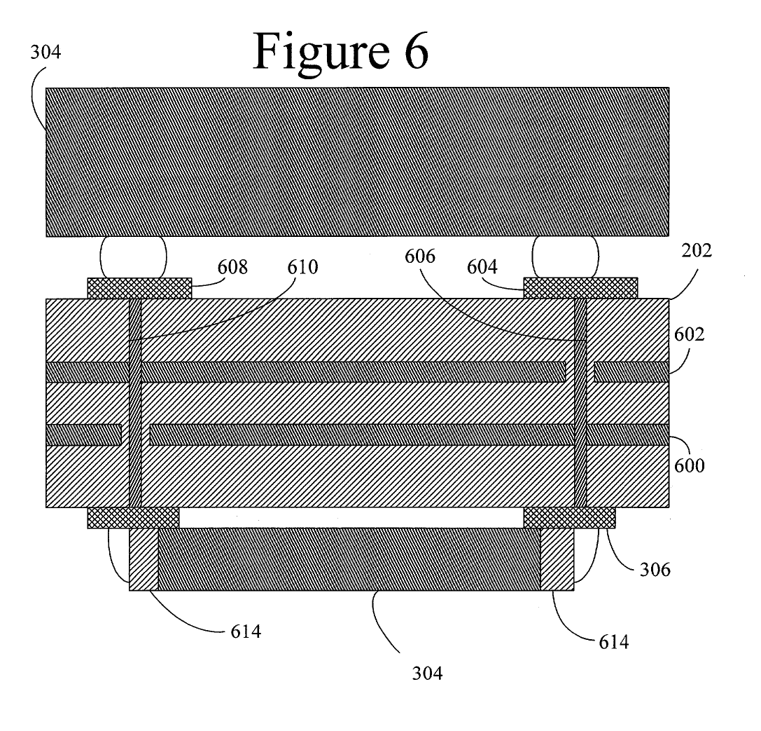

FIG. 6 illustrates a cross sectional view of the printed circuit board 202 in a region adjacent one of the capacitors 304. The capacitor 304 may be mounted to the printed circuit board 202 using any of a variety of conventional techniques. For example, a chemical adhesive may be used to affix the body of the capacitor 304 to the printed circuit board 202. The capacitor 304 may be coupled to the pads 306 using any of a variety of well-known techniques. For example, in the embodiment illustrated in FIG. 6, a pair of contacts 614 are formed on the body of the capacitor 304 and are coupled to the pads 306. Typically, the contacts 614 are soldered to the pads 306. In one embodiment, the pads 306 take the form of a via in pad (VIP), owing to space limitations.

As can be seen in the cross sectional view, the printed circuit board 202 includes at least two power planes (e.g., V_{cc} and ground) 600, 602. A pad 604 associated with the semiconductor device 200 is electrically coupled to the first power plane 600 through a via 606. Similarly, a second pad 608 associated with the semiconductor device 200 is electrically coupled to the second power plane 602 through a via 610. The electrical connection between the pads 604, 608 and the power planes 600, 602 may be accomplished by any of a variety of conventional techniques. For example, the printed circuit board 202 may use the vias 606, 610 that are electrically coupled to the power planes 600, 602. Integrally forming, soldering, or otherwise physically coupling the pads 604, 608 to these vias 606, 610 will connect the pads 604, 606 to the power planes 600, 602 as desired.

Those skilled in the art will appreciate that openings in the power planes 600, 602 permit the vias 606, 610 to pass therethrough without being directly electrically coupled thereto. Additionally, those skilled in the art will appreciate that where multiple voltage supplies are present, multiple power planes may also be used and decoupling capacitors may be positioned and connected to extend between the pads of the semiconductor device that are associated with these various multiple power planes to ensure adequate decoupling of each of the power supplies.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope of the invention. Accordingly, the protection sought herein is as set forth in the claims below.

What is claimed:

1. A method for decoupling a voltage supply from a semiconductor device, comprising:
forming a pattern of spaced apart electrical connections on a first surface of a substrate wherein at least first and second ones of said connections are coupled to first and second terminals of the voltage supply respectively;
positioning a capacitor on a second surface of said substrate positioned adjacent the spaced apart connections, said capacitor having first and second leads coupled with said first and second ones of said connections; and
coupling a semiconductor device adjacent the first surface of said substrate in mating relationship with the pattern of spaced apart electrical connections, wherein said capacitor is positioned adjacent said semiconductor device.

2. A method, as set forth in claim 1, wherein positioning the capacitor on the second surface of said substrate further comprises positioning the capacitor immediately adjacent at least one of the first and second ones of said connections.

3. A method, as set forth in claim 1, wherein positioning the capacitor on the second surface of said substrate further comprises positioning a plurality of capacitors on said substrate interstitially positioned within the spaced apart connections, each of said plurality of capacitor having first and second leads coupled with said first and second ones of said connections.

4. A method, as set forth in claim 1, wherein positioning the capacitor on the second surface of said substrate further comprises positioning the capacitor on a second, opposite side of the substrate.

5. A method, as set forth in claim 1, further comprising forming a power plane positioned within said substrate and electrically coupling at least one of the first and second terminals of the voltage supply to at least one of the first and second ones of the electrical connections.

6. A method, as set forth in claim 1, further comprising forming a first power plane positioned within said substrate and electrically coupling the first terminal of the voltage supply to the first one of the electrical connections.

7. An apparatus for decoupling a voltage supply from a semiconductor device, comprising:
means for forming a pattern of spaced apart electrical connections on a first surface of a substrate wherein at least first and second ones of said connections are coupled to first and second terminals of the voltage supply respectively;
means for positioning a capacitor on a second surface of said substrate positioned adjacent the spaced apart connections, said capacitor having first and second leads coupled with said first and second ones of said connections; and
means for coupling a semiconductor device adjacent the first surface of said substrate in mating relationship with the pattern of spaced apart electrical connections, wherein said capacitor is positioned opposite said semiconductor device.

8. An apparatus, comprising:
a substrate;
a plurality of spaced apart electrical connections positioned on a first surface of the substrate wherein at least first and second ones of said connections are coupled to first and second terminals of a voltage supply respectively;
a capacitor coupled to a second surface of said substrate and positioned within the spaced apart connections, said capacitor having first and second leads coupled with said first and second ones of said connections;
a semiconductor device coupled to said substrate in mating relationship with the pattern of spaced apart electrical connections, wherein said capacitor is positioned adjacent said semiconductor device.

9. An apparatus, as set forth in claim 8, wherein the capacitor is positioned adjacent at least one of the first and second ones of said connections.

10. An apparatus, as set forth in claim 8, wherein the capacitor is positioned immediately adjacent at least one of the first and second ones of said connections.

11. An apparatus, as set forth in claim 8, further comprising a plurality of capacitors located on said second surface of said substrate and interstitially positioned within the spaced apart connections, each of said plurality of capacitors having first and second leads coupled with the first and second ones of said connections.

12. An apparatus, as set forth in claim 8, wherein the capacitor is postioned on said substrate interstitially positioned within the spaced apart connections on the second surface of the substrate.

13. An apparatus, as set forth in claim 8, further comprising a power plane positioned within said substrate and electrically coupled between at least one of the first and second terminals of the voltage supply and at least one of the first and second ones of the electrical connections.

14. An apparatus, as set forth in claim 8, further comprising a first power plane positioned within said substrate and electrically coupling the first terminal of the voltage supply to the first one of the electrical connections, and a second power plane positioned within said substrate and electrically coupling the second terminal of the voltage supply to the second one of the electrical connections.

15. An apparatus, comprising:
a substrate;
a plurality of spaced apart electrical connections positioned on a first surface of the substrate wherein at least first and second ones of said connections are coupled to first and second terminals of a voltage supply respectively;
a capacitor coupled to a second surface of said substrate and positioned within the spaced apart connections immediately adjacent at least one of the first and second ones of said connections, said capacitor having first and second leads coupled with the first and second ones of said connections;
a semiconductor device coupled to said substrate in mating relationship with the pattern of spaced apart electrical connections, wherein said capacitor is positioned adjacent said semiconductor device.

16. A method for decoupling a voltage supply from a semiconductor device, comprising:
forming a pattern of spaced apart electrical connections on a first surface of said substrate wherein at least first and second ones of said connections are coupled to first and second terminals of the voltage supply respectively;
positioning a capacitor on a second, opposite surface of said substrate interstitially positioned within and immediately adjacent at least one of the first and second ones of the connections, said capacitor having first and second leads coupled with the first and second ones of said connections;
coupling a semiconductor device to said substrate in mating relationship with the pattern of spaced apart electrical connections, wherein said capacitor is positioned adjacent said semiconductor device.
